(19) United States
(12) Patent Application Publication
(10) Pub. No.: US 2023/0343893 A1
(43) Pub. Date: Oct. 26, 2023

(54) LED EPITAXIAL STRUCTURE AND LED CHIP

(71) Applicant: XIAMEN SILAN ADVANCED COMPOUND SEMICONDUCTOR CO., LTD., Xiamen (CN)

(72) Inventors: Senlin Li, Xiamen (CN); Yahong Wang, Xiamen (CN); Meijia Yang, Xiamen (CN); Jingfeng Bi, Xiamen (CN); Weihong Fan, Xiamen (CN)

(21) Appl. No.: 18/005,419

(22) PCT Filed: Mar. 1, 2022
(86) PCT No.: PCT/CN2022/078637

§ 371 Date: Jan. 13, 2023

(30) Foreign Application Priority Data
Jun. 30, 2021 (CN) 202110736652.1

(51) Int. Cl. H01L 33/10; H01L 33/30

(52) U.S. Cl. CPC H01L 33/10; H01L 33/30

(57) ABSTRACT

The present disclosure relates to an epitaxial structure for light emitting diode and a light emitting diode. The epitaxial structure for light emitting diode comprises a substrate, a buffer layer, a distributed Bragg reflector, and a semiconductor stack in an order from bottom to top. The distributed Bragg reflector includes a low refractive-index film and a high refractive-index film above the low refractive-index film, and a thickness of the high refractive-index film is thinner than an optical thickness of the high refractive-index film. The present disclosure can reduce light absorption of the distributed Bragg reflector and improve reflectivity and light output intensity of the distributed Bragg reflector by adjusting the thickness of the high refractive-index film.

### CROSS-REFERENCE TO RELATED APPLICATION(S)

The present application is a Section 371 National Stage Application of International Application No. PCT/CN2022/078637, filed on Mar. 1, 2022, and published as WO 2023/273374 A1, on Jan. 5, 2023, not in English, which claims priority to Chinese patent application No. 202110736652.1, filed on Jun. 30, 2021, entitled “EPITAXIAL STRUCTURE FOR LIGHT EMITTING DIODE AND LIGHT EMITTING DIODE”, the disclosures of which are herein incorporated by reference in their entireties.

### FIELD OF THE DISCLOSURE

The present disclosure relates to the technical field of semiconductors, in particular to an epitaxial structure for light emitting diode and a light emitting diode.

### DESCRIPTION OF THE RELATED ART

A light-emitting diode (LED) has attracted more and more attention because it has high efficiency and low power consumption, and is environmentally friendly. It can be seen everywhere in daily life, and is widely used in traffic signal lights, display screens, night lighting and plant lighting.

A light-emitting diode appeared as early as in 1962. It can only emit red light with low-luminosity in an early stage, and then is gradually developed to emit various monochromatic lights. Up to now, the light-emitting diode has a light spectrum which covers all of visible light, infrared light and ultraviolet light, and its brightness is significantly improved.

Today, there is an increased demand for light with wavelength of 565 nm˜640 nm. However, when fabricating a light emitting diode with a short wavelength, there will have light absorption problem for a conventional distributed Bragg reflector (DBR), which will lead to decreased reflectivity of the DBR and decreased brightness of the light emitting diode. These problems need to be solved.

### SUMMARY OF THE DISCLOSURE

One object of the present disclosure is to provide an epitaxial structure for light emitting diode and a light emitting diode to solve light absorption problem of distributed Bragg reflector with a short wavelength, which is beneficial to improve reflectivity of the distributed Bragg reflector and light output intensity of the light emitting diode.

In order to achieve the above and other related objects, the present disclosure provides an epitaxial structure for light emitting diode comprising a substrate, a buffer layer, a distributed Bragg reflector, and a semiconductor stack in an order from bottom to top, wherein the distributed Bragg reflector includes a low refractive-index film and a high refractive-index film above the low refractive-index film, and a thickness of the high refractive-index film is thinner than an optical thickness of the high refractive-index film.

Preferably, in the epitaxial structure for light emitting diode as mentioned above, the low refractive-index film comprises Al_{z}Ga_{1-z}As, where 95%≥z≥100%.

Preferably, in the epitaxial structure for light emitting diode as mentioned above, the distributed Bragg reflector is a periodic structure consisting of the low refractive-index film and the high refractive-index film, and a number of periods of the distributed Bragg reflector is in the range of 10 to 100.

Preferably, in the epitaxial structure for light emitting diode as mentioned above, the thickness of the low refractive-index film is thicker than an optical thickness of the low refractive-index film by d₁, and a range of d₁ is 0.05 D₁ to 0.4 D₁, where D₁ is the optical thickness of the low refractive-index film, and D₁=λ/4N₁, N₁ is a refractive index of the low refractive-index film, and λ is a central reflection wavelength.

Preferably, in the epitaxial structure for light emitting diode as mentioned above, the thickness of the low refractive-index film ranges from 30 nm to 70 nm.

Preferably, in the epitaxial structure for light emitting diode as mentioned above, the high refractive-index film comprises a first high refractive-index film and a second high refractive-index film above the first high refractive-index film, and thickness and composition of the first high refractive-index film are different from those of the second high refractive-index film.

Preferably, in the epitaxial structure for light emitting diode as mentioned above, the first high refractive-index film comprises Al_{y}Ga_{1-y}As, where 70%≥y≥50%.

Preferably, in the epitaxial structure for light emitting diode as mentioned above, the second high refractive-index film comprises AlₓGa₁₋ₓAs, where 65%≥x≥0.

Preferably, in the epitaxial structure for light emitting diode as mentioned above, a composition ratio of Al of the second high refractive-index film is not higher than that of the first high refractive-index film.

Preferably, in the epitaxial structure for light emitting diode as mentioned above, the thickness of the second high refractive-index film is thinner than an optical thickness of the second high refractive-index film by 2d₂, and a range of d₂ is 0.05 D₂ to 0.4 D₂, where D₂ is the optical thickness of the second high refractive-index film, and D₂=λ/4N₂, N₂ is a refractive index of the second high refractive-index film, and λ is a central reflection wavelength.

Preferably, in the epitaxial structure for light emitting diode as mentioned above, the thickness of the second high refractive-index film ranges from 20 nm to 60 nm.

Preferably, in the epitaxial structure for light emitting diode as mentioned above, the thickness of the first high refractive-index film is d₂.

Preferably, in the epitaxial structure for light emitting diode as mentioned above, the substrate is any one of a GaAs substrate and a Si substrate.

Preferably, in the epitaxial structure for light emitting diode as mentioned above, the semiconductor stack comprises a first semiconductor layer, an active layer, a second semiconductor layer and a window layer which are formed in order on the distributed Bragg reflector.

In order to achieve the above and other related objects, the present disclosure provides a light emitting diode comprising a first electrode layer, an epitaxial structure for light emitting diode as mentioned above, a current spreading layer, and a second electrode layer from bottom to top.

Because the high refractive-index film is made of a material which has light absorption larger than that of the low refractive-index film, the high refractive-index film can have reduced light absorption by decreasing its thickness. Reflectivity of the distributed Bragg reflector and light output intensity of the light emitting diode can be improved. Meanwhile, a first high refractive-index film is sandwiched between the low refractive-index film and a second high refractive-index film, which forms high refractive-index films having a gradient refractive-index with the second high refractive-index film. The first high refractive-index film is a buffer layer which improves lattice matching and reduces light absorption due to lattice mismatching when light is reflected.

### BRIEF DESCRIPTION OF THE DRAWINGS

FIG. 1 is a structural schematic diagram of a light emitting diode according to an embodiment of the present disclosure;

FIG. 2 is a schematic structural diagram of a distributed Bragg reflector according to an embodiment of the present disclosure.

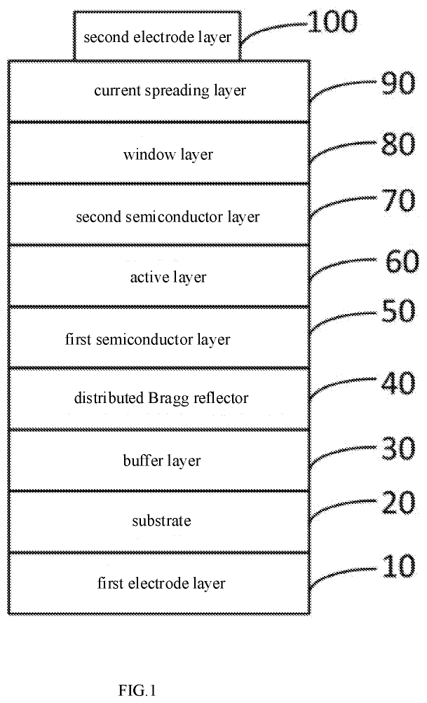

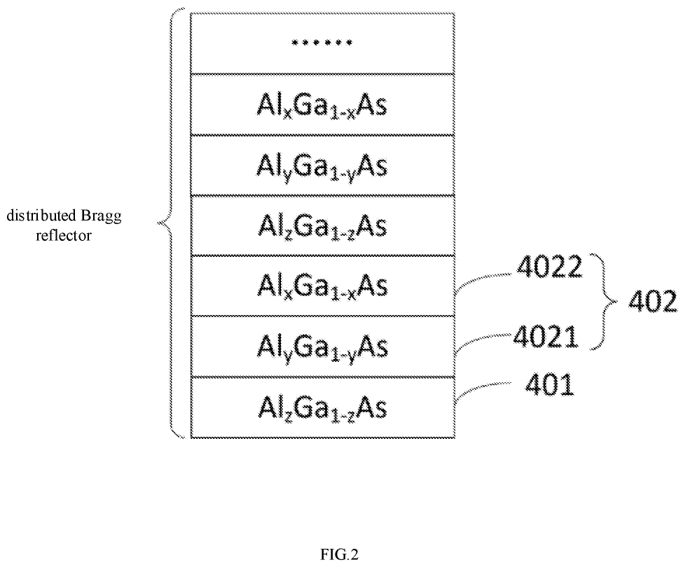

In FIGS. 1 and 2:

10—first electrode layer, 20—substrate, 30—buffer layer, 40—distributed Bragg reflector, 401—low refractive-index film, 402—high refractive-index film, 4021—first high refractive-index film, 4022—second high refractive-index film, 50—first semiconductor layer, 60—active layer, 70—second semiconductor layer, 80—window layer, 90—current spreading layer, 100—second electrode layer.

### DETAILED DESCRIPTION OF EMBODIMENTS OF THE DISCLOSURE

A light-emitting diode (LED) has attracted more and more attention because it has high efficiency and low power consumption, and is environmentally friendly. The light-emitting diode (LED) emits light through combination of electrons and holes, and is widely used as a light-emitting device in the field of illumination. The light-emitting diode can efficiently convert electric energy into light energy. It can only emit red light with low-luminosity in an early stage, and then is gradually developed to emit various monochromatic lights. Up to now, the light-emitting diode has a light spectrum which covers all of visible light, infrared light and ultraviolet light, and its brightness is significantly improved.

Today, there is an increased demand for light with a short wavelength. However, when fabricating a light emitting diode with a short wavelength, there will have light absorption problem for a conventional distributed Bragg mirror (DBR) stack, which will lead to decreased reflectivity of the DBR and decreased luminosity of the light emitting diode. When fabricating the light emitting diode with a short wavelength, problems such as low light output and low reflectivity need to be solved.

The present disclosure provides an epitaxial structure for light emitting diode and a light emitting diode, so as to solve a light absorption problem of the distributed Bragg reflector for a short wavelength, and to increase reflectivity of the distributed Bragg reflector, and to improve light output intensity and reflectivity of the light emitting diode.

The epitaxial structure for light emitting diode and the light emitting diode according to the present disclosure will be described in detail below with reference to the drawings and specific embodiments. According to the following specification, the advantages and characteristics of the present disclosure will be clearer. It should be noted that the drawings are in a very simplified form and use imprecise proportions, and are only used to facilitate and clearly assist in illustrating the purposes of the present disclosure embodiments.

Referring to FIG. 1 the light emitting diode includes a first electrode layer 10, an epitaxial structure for light emitting diode, a current spreading layer 90, and a second electrode layer 100 in an order from bottom to top.

The epitaxial structure for light emitting diode comprises a substrate 20, a buffer layer 30, a distributed Bragg reflector (DBR) 40, and a semiconductor stack in an order from bottom to top.

The substrate 20 is preferably a GaAs (gallium arsenide) substrate or a Si substrate, and includes a front surface, for growing the buffer layer 30, and a back surface opposite to the front surface, for growing the first electrode layer 10. The thickness of the substrate 20 is not particularly limited.

The buffer layer 30 is formed on the substrate 20, and may be made of AlGaAs or GaAs, preferably AlGaAs. The buffer layer 30 is used to reduce the lattice mismatching between the substrate 20 and the epitaxial layer, so as to reduce occurrence of defects and dislocations in the epitaxial layer and improve the crystal quality. The buffer layer 30 is preferably deposited by MOCVD (Metal Organic Chemical Vapor Deposition).

A distributed Bragg reflector 40 is formed on the buffer layer 30. The distributed Bragg reflector 40 is a multilayer periodic structure consisting of two materials with different refractive indices, and reflects light which is emitted from the active layer 60 and transmitted to the substrate to a top surface, thereby greatly improving light output efficiency. Moreover, the distributed Bragg reflector has a crystal lattice highly matched with a GaAs substrate and has high reflectivity, with little influence on electrochemical characteristics of the device. Therefore, an epitaxial structure of a light emitting diode (LED) with a short wavelength can improve light output by an additional distributed Bragg reflector.

According to optical film theory, the distributed Bragg reflector has increased spectral reflectivity and full width at half maximum in a case that the difference between refractive indices of two materials increases. Thus, in order to obtain a better reflective spectrum of the distributed Bragg reflector, the refractive indices of the two materials should have a difference as large as possible.

Because the distributed Bragg reflector is formed by stacking two materials of a high refractive index and a low refractive index respectively, each of which has an optical thickness of a quarter wavelength. An optical thickness of one layer can be calculated according to a theoretical formula D=λ/4N, where D is an optical thickness of the layer, λ is a central reflection wavelength, and N is a refractive index of material of the layer.

Referring to FIG. 2, in this embodiment, the distributed Bragg reflector 40 has a periodic structure. The distributed Bragg reflector 40 includes a low refractive-index film 401 and a high refractive-index film 402 above the low refractive-index film 401 in each period. That is, the distributed Bragg reflector 40 is a periodic structure consisting of the low refractive-index film 401 and the high refractive-index film 402.

Preferably, the low refractive-index film 401 may be made of Al_{z}Ga_{1-z}As, where 95%≥z≥100%. A thickness of the low refractive-index film 401 is thicker than an optical thickness of the low refractive-index film 401. Moreover, the thickness of the low-refractive-index film 401 is thicker by d₁ than the optical thickness of the low-refractive-index film 401. That is, the thickness of the low-refractive-index film 401 increases by d₁ on the basis of the optical thickness of the low-refractive-index film 401, so that the thickness of the low-refractive-index film 401 deviates from its optical thickness. The inventor's research reaches the result that the thickness of the low refractive-index film 401 preferably deviates from the optical thickness of the low refractive-index film 401 in a range of 5% to 40%. That is, d₁=0.05D₁˜0.4 D₁, D₁=λ/4N₁, where D₁ is the optical thickness of the low refractive-index film 401, λ is a central reflection wavelength, and N₁ is a refractive index of the low refractive-index film 401. Therefore, the thickness of the low refractive-index film 401 is D₁+d₁. Moreover, the thickness of the low refractive-index film 401 ranges preferably from 30 nm to 70 nm, including the deviation of 5% to 40%.

The high refractive-index film 402 includes a first high refractive-index film 4021 and a second high refractive-index film 4022, and the second high refractive-index film 4022 is located on the first high refractive-index film 4021. The second high refractive-index film 4022 has a thickness and a composition different from those of the first high refractive-index film 4021. The first high refractive-index film 4021 may be made of Al_{y}Ga_{1-y}As, where 70%≥y≥50%. The second high-refractive-index film 4022 may be made of AlₓGa₁₋ₓAs, where 65%≥x≥0, and a composition ratio of Al of the second high-refractive-index film 4022 is not higher than that of the first high-refractive-index film 4021, i.e. x≤y.

The thickness of the second high refractive-index film 4022 is thinner than an optical thickness of the second high refractive-index film 4022 by 2d₂. The optical thickness of the second high refractive-index film 4022 is D₂, and D₂=λ/4N₂, wherein 2 is a central reflection wavelength and N₂ is a refractive index of the second high refractive-index film 4022, where d₂=0.05 D₂˜0.4 D₂. Therefore, the thickness of the second high refractive-index film 4022 is D₂−2d₂. Furthermore, the thickness of the second high refractive-index film 4022 ranges preferably from 20 nm to 60 nm, after the deviated thickness 2d₂ has been subtracted.

The thickness of the first high refractive-index film 4021 is preferably d₂, that is, the thickness of the first high refractive-index film 4021 is 0.05 D₂ to 0.4 D₂. The first high refractive-index film 4021 has a thickness and a composition different from those of the second high refractive-index film 4022, and forms high refractive-index films 402 having a gradient refractive-index with the second high refractive-index film 4022. The first high refractive-index film 4021 is a buffer layer which improves lattice matching, reduces stress and dislocation due to lattice mismatching, and thus reduces light absorption.

Referring back to FIG. 2, the distributed Bragg reflector 40 is a periodic structure of Al_{z}Ga_{1-z}As/Al_{y}Ga_{1-y}As/AlₓGa₁₋ₓAs, which constitute one period and are repeatedly grown one period by another period. A number of periods of the distributed Bragg reflector 40 is preferably in the range of 10 to 100. In a case light is emitted with a short wavelength, the light will be strongly absorbed. The wavelength is determined by adjusting thicknesses of three layers including a low refractive-index film/a first high refractive-index film/a second high refractive-index film.

When designing the distributed Bragg reflector 40 with a short wavelength, Fresnel reflection occurs at each interface between adjacent layers of different materials according to the principle of Bragg mirror. Thus, all of the reflected lights at various interfaces undergo destructive interference to obtain the light being strongly reflected. The low refractive-index film 401 is preferably made of Al_{z}Ga_{1-z}As, for example Al_{0.95}Ga_{0.05}As. Light absorption of the high refractive-index film 402 is larger than that of the low refractive-index film 401. Therefore, in this embodiment, by reducing the thickness of the high refractive-index film 402, light absorption will be alleviated, and reflectivity of the distributed Bragg reflector and the light output intensity of the light emitting diode are improved.

A first semiconductor layer 50 is grown on the distributed Bragg reflector 40. The first semiconductor layer 50 may be made of N—AlGaInP. The process is preferably metal organic chemical vapor deposition. Because the first semiconductor layer 50 is an existing structure, it will not be described here.

an active layer 60 is grown on the first semiconductor layer 50. The active layer 60 is preferably made of Al_{0.8}GA_{0.2}InP/Al_{0.15}Ga_{0.85}InP, but is not limited thereto. The process is preferably metal organic chemical vapor deposition. Because the active layer 60 is an existing structure, it will not be described here.

A second semiconductor layer 70 is grown on the active layer 60. The second semiconductor layer 70 may be made of P—AlGaInP. The process is preferably metal organic chemical vapor deposition. Because the second semiconductor layer 70 is an existing structure, it will not be described here.

A window layer 80 is grown on the second semiconductor layer 70. The window layer 80 may be made of GaP. The process is preferably metal organic chemical vapor deposition. Because the window layer 80 is an existing structure, it will not be described here.

A current spreading layer 90 is grown on the window layer 80. The current spreading layer 90 is preferably made of ITO (Indium Tin Oxide). The process of the current spreading layer 90 may include magnetron sputtering method, reactive thermal evaporation method, electron beam evaporation, etc. The ITO is preferably formed by electron beam evaporation or magnetron sputtering method.

A second electrode layer 100 is formed on the current spreading layer 90. The second electrode layer 100 covers a part of the surface of the current spreading layer 90. Because the process of forming the second electrode layer 100 is a prior art, it will not be described here.

A first electrode layer 10 is formed on the back surface of the substrate 20, and the first electrode layer 10 can be used as a contact metal layer. The first electrode layer 10 is preferably made of metal, and further preferably, one or more of Pt, Ti, Cr, W, Au, Al, Ag, or the like. The first electrode layer 10 is formed on the back surface of the substrate 20 by evaporation or sputtering. Because the first electrode layer 10 is an existing structure, it will not be described here.

To sum up, in the epitaxial structure for light emitting diode and light emitting diode according to the present disclosure, the epitaxial structure for light emitting diode comprises a substrate, a buffer layer, a distributed Bragg reflector, and a semiconductor stack in an order from bottom to top, wherein the distributed Bragg reflector includes a low refractive-index film and a high refractive-index film above the low refractive-index film, and a thickness of the high refractive-index film is thinner than an optical thickness of the high refractive-index film. Because the high refractive-index film is made of a material which has light absorption larger than that of the low refractive-index film, the high refractive-index film can have reduced light absorption by decreasing its thickness. Reflectivity of the distributed Bragg reflector and light output intensity of the light emitting diode can be improved. Meanwhile, a first high refractive-index film is sandwiched between the low refractive-index film and a second high refractive-index film, which forms high refractive-index films having a gradient refractive-index with the second high refractive-index film. The first high refractive-index film is a buffer layer which improves lattice matching and reduces light absorption due to lattice mismatching when light is reflected.

Furthermore, it is to be understood that although the present disclosure has disclosed as above with preferred embodiments, the above embodiments are not intended to limit the present disclosure. To anyone skilled in the art, many possible variations and modifications, or modifications to equivalent embodiments of equivalent variations, may be made to the present disclosure technical proposal using the above-disclosed technical aspects without departing from the scope of the present disclosure technical proposal. Therefore, any simple modifications, equivalent changes and modifications made to the above embodiments according to the technical essence of the present disclosure that are not divorced from the technical scheme of the present disclosure are still within the scope of protection of the technical scheme of the present disclosure.

It should also be understood that the present disclosure is not limited to the specific methods, compounds, materials, manufacturing techniques, uses and applications described herein, which may vary. It should also be understood that the terms described herein are used only to describe specific embodiments and are not intended to limit the scope of the present disclosure. It must be noted that the singular forms “a”, “an” and “the” used herein and in the appended claims include plural references, unless the context expressly indicates the contrary. Thus, for example, a reference to “a step” or “a device” means a reference to one or more steps or devices, and may include secondary steps as well as secondary devices. All conjunctions used should be understood in the broadest sense. Thus, the word “or” should be understood as having a logical definition of “or” rather than a logical definition of “exclusive or”, unless the context clearly indicates the contrary. The structure described herein will be understood as also referring to functional equivalents of the structure. Any description may be interpreted as an approximation when it should be understood in that way, unless the context clearly means the contrary.

1. An epitaxial structure for light emitting diode characterized in that the epitaxial structure for light emitting diode comprises a substrate, a buffer layer, a distributed Bragg reflector, and a semiconductor stack in an order from bottom to top, wherein the distributed Bragg reflector includes a low refractive-index film and a high refractive-index film above the low refractive-index film, and a thickness of the high refractive-index film is thinner than an optical thickness of the high refractive-index film.

2. The epitaxial structure for light emitting diode according to claim 1, characterized in that the distributed Bragg reflector is a periodic structure consisting of the low refractive-index film and the high refractive-index film, and a number of periods of the distributed Bragg reflector is in the range of 10 to 100.

3. The epitaxial structure for light emitting diode according to claim 1, wherein the low refractive-index film comprises AlzGa1−zAs, where 95%≥z≥100%.

4. The epitaxial structure for light emitting diode according to claim 1, wherein the thickness of the low refractive-index film is thicker than an optical thickness of the low refractive-index film by d1, and a range of d1 is 0.05 D1 to 0.4 D1, where D1 is the optical thickness of the low refractive-index film, and D1=λ/4N1, N1 is a refractive index of the low refractive-index film, and λ is a central reflection wavelength.

5. The epitaxial structure for light emitting diode according to claim 1, wherein the thickness of the low refractive-index film ranges from 30 nm to 70 nm.

6. The epitaxial structure for light emitting diode according to claim 1, wherein the high refractive-index film comprises a first high refractive-index film and a second high refractive-index film above the first high refractive-index film, and thickness and composition of the first high refractive-index film are different from those of the second high refractive-index film.

7. The epitaxial structure for light emitting diode according to claim 6, wherein the first high refractive-index film comprises AlyGa1−yAs, where 70%≥y≥50%.

8. The epitaxial structure for light emitting diode according to claim 6, wherein the second high refractive-index film comprises AlxGa1−xAs, where 65%≥x≥0.

9. The epitaxial structure for light emitting diode according to claim 6, wherein a composition ratio of Al of the second high refractive-index film is not higher than that of the first high refractive-index film.

10. The epitaxial structure for light emitting diode according to claim 6, characterized in that the thickness of the second high refractive-index film is thinner than an optical thickness of the second high refractive-index film by 2d2, and a range of d2 is 0.05 D2 to 0.4 D2, where D2 is the optical thickness of the second high refractive-index film, and D2=λ/4N2, N2 is a refractive index of the second high refractive-index film, and λ is a central reflection wavelength.

11. The epitaxial structure for light emitting diode according to claim 10, wherein the thickness of the first high refractive-index film is d2.

12. The epitaxial structure for light emitting diode according to claim 6, wherein the thickness of the second high refractive-index film ranges from 20 nm to 60 nm.

13. The epitaxial structure for light emitting diode according to claim 1, wherein the substrate is any one of a GaAs substrate and a Si substrate.

14. The epitaxial structure for light emitting diode according to claim 1, wherein the semiconductor stack comprises a first semiconductor layer, an active layer, a second semiconductor layer and a window layer which are formed in order on the distributed Bragg reflector.

15. A light emitting diode comprising a first electrode layer, an epitaxial structure for light emitting diode according to claim 1, a current spreading layer, and a second electrode layer from bottom to top.
